(19) United States
(12) Patent Application Publication
(10) Pub. No.: US 2006/0157819 A1
(43) Pub. Date: Jul. 20, 2006

(54) EFUSE STRUCTURE

(76) Inventor: Bing-Chang Wu, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 10/905,770

(22) Filed: Jan. 20, 2005

(51) Int. Cl. H01L 29/00

(52) U.S. Cl. 257/529

(57) ABSTRACT

A surface of a semiconductor substrate comprises at least one electrical conduction structure and at least one eFuse. The electrical conduction structure comprises a first poly silicon layer and a first poly silicide layer formed in the first poly silicon layer. The eFuse comprises a second poly silicon layer and a second poly silicide layer formed on the second poly silicon layer. The area of the second poly silicide layer is smaller than the area of the first poly silicide layer.

### BACKGROUND OF INVENTION

1. Field of the Invention

The invention relates to a structure of an eFuse, and more particularly, to an eFuse structure in which the poly silicide layer is smaller than the poly silicide layer of a gate structure.

2. Description of the Prior Art

As semiconductor processes become smaller and more complex, semiconductor components are influenced by impurities more easily. If a single metal link, a diode, or a MOS is broken down, the whole chip will be unusable. To treat this problem, fuses can be selectively blown for increasing the yield of IC manufacturing.

In general, fused circuits are redundant circuits of an IC. When defects are found in the circuit, fuses can be selectively blown for repairing or replacing defective circuits. For example, with memory, the top surface of the memory has fuse structures. When the memory cell, word line, or wire contains defects, fuses can be connected with other redundant memory cells, word lines or wires to replace the circuit.

Besides, fuses provide the function of programming circuits for different functions. For reducing cost, every transistor is connected with each other by a metal link and memory array and plus a linked component for programming. After the semiconductor chip is finished, the standard chip can be customized using input data. When a 1 is transmitted into a PROM (Programmable ROM), the linked component for programming is blown open and becomes an open circuit (off-state) forever. Otherwise, the linked component for programming is closed and maintains an on-state when 0 is transmitted into the PROM. The blowing process fuses using input voltages is called programming.

Fuses are divided into two categories based on their operation: thermal fuse and eFuse. Thermal fuses can be cut by lasers and be linked by laser repair. The defective electrical connections of memory cell, word lines, or wires are replaced by new ones. EFuse utilizes electro-migration for both forming open circuits and for repairing.

The current eFuse has the function of using software calculations to respond to outside demands, making the repairing process easier and lowering the cost. This kind of eFuse does not need to be controlled by humans. In short, the eFuse could control the speed of single circuits and could repair unexpected defects. Electro-migration has been a harmful function in the past and was avoided in designs. But eFuse uses electro-migration to produce open circuits and to repair or program ICs successfully.

Please refer to FIG. 1. FIG. 1 is a diagram of an eFuse structure 10 according to the prior art. The eFuse structure 10 comprises an eFuse 12, cathode 14, anode 16 and a linked surface 18 electrically connected between the cathode 14 and the anode 16. In general, the eFuse structure is unused, and is only a redundant circuit. When repairing or programming occurs, the electro-migration will be produced by electricity passing through the eFuse structure 10. FIG. 2 illustrates the electro-migration of the eFuse according to the prior art. When high electricity passed through the eFuse structure 10, the eFuse 12 is the densest region of electricity, the electric field is highest, and atoms will move toward the direction of electron flow along the boundary of the crystalline grain. As electro-migration becomes more and more violent, the density of electricity becomes higher and higher, and the linked surface 18 in FIG. 1 will become an open circuit 28 in FIG. 2 for repairing or programming.

However, the way of controlling an eFuse to open using electro-migration in the prior art is very difficult and suffers from a low repair yield. When voltage is too low, electro-migration will not occur and the circuit cannot become what designer intended. When voltage is too high, the eFuse will be blown, will pollute the IC, or will cause a short. In other words, in the past control voltages have needed to be controlled very carefully. Even so, effuses can only tolerate a small range around the highest voltage such as 5%. If the highest voltage is over the tolerance range, the eFuse will be blown improperly. Even if we use expensive instruments to control the electricity and voltage levels, this still may not be enough to properly control the eFuse. Therefore, creating an eFuse structure that can be opened accurately is a very important subject

### SUMMARY OF INVENTION

The invention relates to an eFuse structure to solve the above problems.

The embodiment according to the present invention provides an eFuse structure formed in a substrate, the eFuse structure comprising at least an electrical conduction structure. The electrical conduction structure comprises a first poly silicon layer and a first poly silicide layer formed in the first poly silicon layer, a second poly silicon layer and a second poly silicide layer formed in the second poly silicon layer, wherein an area of the second poly silicide layer is smaller than the first poly silicide layer.

Another embodiment according to the present invention provides an eFuse structure formed in a substrate, a stacked eFuse structure manufactured in a same process as a stacked gate structure and the thickness of the eFuse structure being thinner than the thickness of the gate structure.

Because of the thinner poly silicide layer according to the present invention, the eFuse structure is blown easily to solve the past problem of being hard to control, thereby increasing the repair yield. Furthermore, the thicker poly silicide of the gate makes the electricity stable. The gate structure and eFuse structure are similar and could be completed in the same process, so the manufacturing is simpler and the cost is lower.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is diagram of an eFuse structure according to the prior art.

FIG. 2 is diagram of the electro-migration of the eFuse according to the prior art.

FIGS. 3 to 7 are diagrams of the manufacturing process of an eFuse structure on a semiconductor chip according to the present invention.

FIG. 8 is another diagram of the manufacturing process of the eFuse structure on a semiconductor chip according to the present invention.

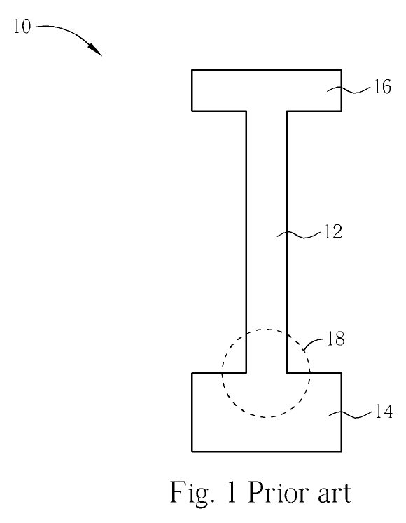

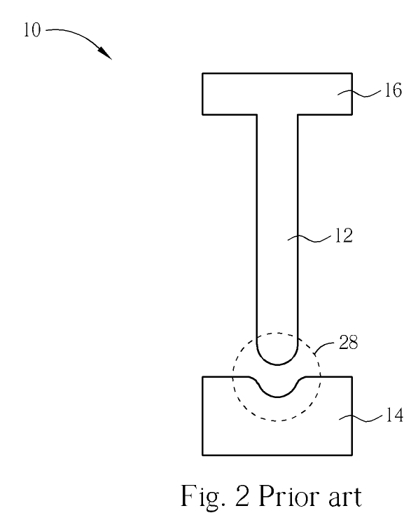

### DETAILED DESCRIPTION

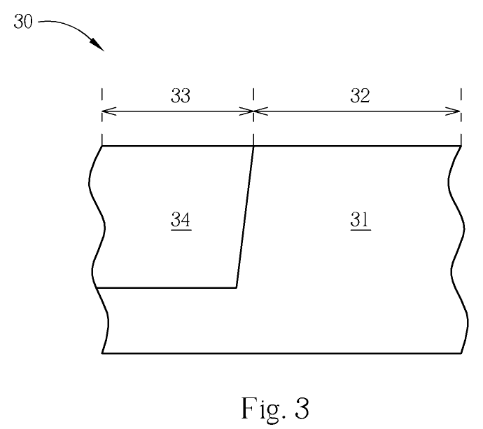

Please refer to FIGS. 3 to 7. FIGS. 3 to 7 are diagrams of the manufacturing process of an eFuse structure on a semiconductor chip according to the present invention. As shown in FIG. 3, a semiconductor chip 30 comprises a substrate 31 and surface of the substrate 31 includes a first region 32 and a second region 33. The second region 33 forms a plurality of insulting layers called STI (shallow trench isolation) layers or field oxide layers by utilizing a shallow trench isolation process or local oxidation (LOCOS) to surround and isolate the first region 32. The first region 32 forms an active area for a MOS.

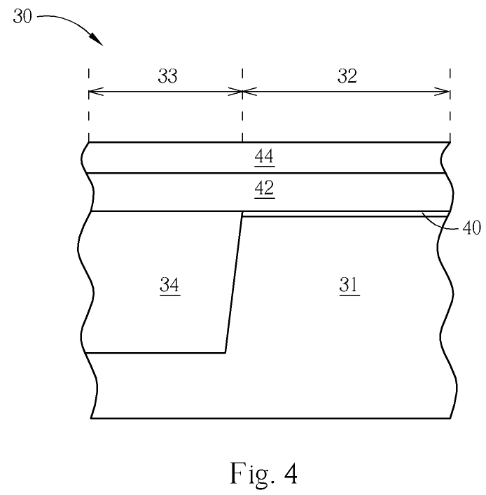

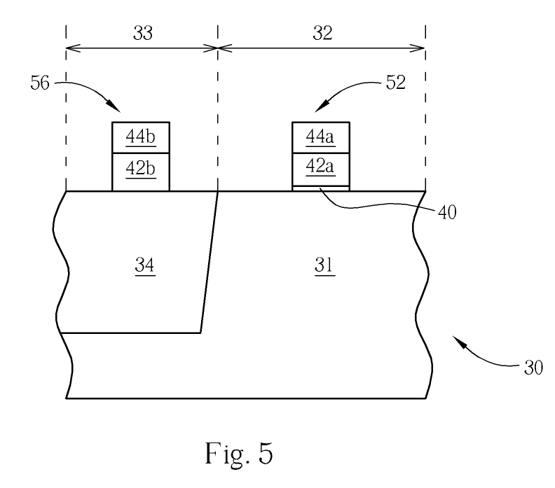

FIG. 4 illustrates a thermal oxidation or CVD (chemical vapor deposition) process used to form silicon dioxide or silicon nitride as a gate insulating layer 40. The depth of the gate insulating layer 40 is almost matched with the surface of the STI (shallow trench isolation) 34. The deposition process forms a poly silicon layer 42 and a poly silicide layer 44. The first region 32 forms the gate structure 52 comprising a poly silicon layer 42a and a poly silicide layer 44a by PEP. And the second region 33 forms the structure of an eFuse 56 comprising poly silicon layer 42b and poly silicide layer 44b by PEP. As shown in FIG. 5, the poly silicon layers 42a and 42b have the same layer depth, because of one etching process. And the layer depth of the poly silicide layers 44a and 44b are the same for the same reason. But, the layer depth of the poly silicide layers 44a and 44b are not equal with the layer depth of poly silicon layers 42a and 42b. The line widths of poly silicon layers 42a and 42b can be equal or unequal with the line width of poly silicide layer 44a and 44b. In the embodiment of the present invention, the line widths of poly silicon layers 42a and 42b are equal.

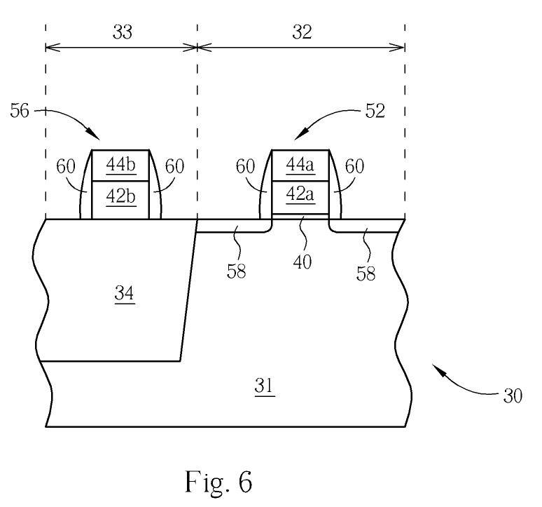

As shown in FIG. 6, the ion implantation process forms a LDD (lightly doped drain) 58 on the lateral sides of the gate structure 52. The surface of semiconductor chip 30 has a silicon nitride layer (not shown) doped by CVD. Then, spacers 60 surrounding the gate structure 52 and the structure of an eFuse 56 are formed by an anisotropic dry etching etched on the silicon nitride.

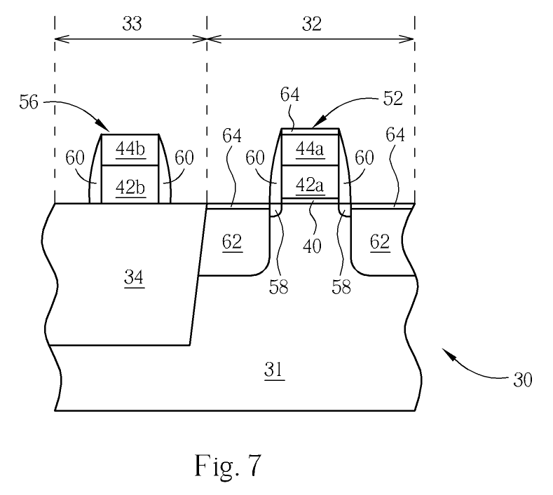

As shown in FIG. 7, the ion implantation process forms drain 62 and source 62 on the lateral sides of the gate structure 52. A salicide block layer 64 covers the second region 33. The silicide layer 64 is formed on the surface of the gate structure 52, the source 62 and the drain 62 by a self-aligned silicide process. The total layer depth of the poly silicide layer of gate structure 52 (the layer depth of the poly silicide layer 44a plus the layer depth of the salicide layer 64) is higher than the layer depth of the poly silicide layer 44b of the eFuse structure 56. The poly silicon layer 42a, 42b and the poly silicide layers 44a and 44b have the same line width. The area of the poly silicide layer of the gate structure 52 is bigger than the area of the poly silicide layer of the eFuse structure 56.

The eFuse structure in the present invention has a thinner poly silicide layer that can be blown easily. This structure can solve the past problem of low control and can also increase the repair yield. Furthermore, the thicker poly silicide of gate makes the electricity stable.

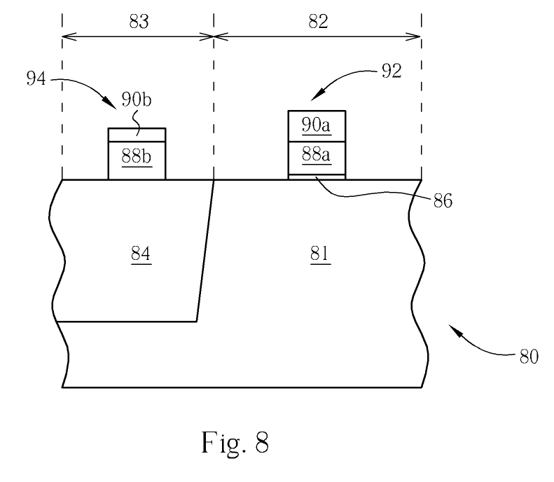

Please refer to FIG. 8. FIG. 8 is another diagram of the manufacturing process of the eFuse structure on the semiconductor chip according to the present invention. The process of forming the poly silicide layer in FIG. 8 is different from FIGS. 3 to 7. The semiconductor chip 80 comprises a substrate 81 and the surface of the substrate 81 includes a first region 82 and a second region 83. The second region 83 forms a plurality of insulting layers called STI (shallow trench isolation) or field oxide layers by a shallow trench isolation process or local oxidation (LOCOS) to surround and isolate the first region 82. The first region 82 forms an active area for a MOS.

The thermal oxidation or CVD (chemical vapor deposition) process forms a gate insulating layer 86 in the first region 82. The deposition process forms a poly silicon layer (not shown) and a poly silicide layer (not shown). The first region 82 forms the gate structure 92 comprising a poly silicon layer 88a and a poly silicide layer 90a by PEP with a half-tone mask. And the second region 83 forms the eFuse structure 94 comprising a poly silicon layer 88b and a poly silicide layer 90b by PEP with a half-tone mask. The poly silicon layers 88a and 88b have the same layer depth. But the layer depth of the poly silicide layer 90a is different from the layer depth of the poly silicide layer 90b, because of the half-tone mask. And, the layer depth of the poly silicide layer 90a of the gate structure 92 is higher than the layer depth of poly silicide layer 90b of the eFuse structure 94. In FIG. 8, the line width of the gate structure is the same as the line width of the eFuse structure. Otherwise, there are many ways to form different layer depths of poly silicide layers such as doping many times followed by one etching or with one doping followed by etching many times. Any of these ways could make the layer depth of poly silicide layer 90a of the gate structure 82 higher than the layer depth of poly silicide layer 90b of the eFuse structure 94.

Compared to the prior art, the present invention provides an eFuse structure, the poly silicide layer of the eFuse structure being smaller than the poly silicide layer of the gate structure. Because of the thinner poly silicide layer according to the present invention, the eFuse structure is blown easily to solve the past problem of low control and increases the repair yield. Moreover, the thicker poly silicide of gate makes the electricity stable. The gate structure and eFuse are similar and could be completed in the same process, so the manufacturing process is simpler and the cost is lower.

Those skilled in the art will readily observe that numerous modifications and alterations of the device and method may be made while retaining the teachings of the invention. Accordingly, the above disclosure should be construed as limited only by the metes and bounds of the appended claims.

1. An eFuse structure formed in a substrate comprising at least an electrical conduction structure, the electrical conduction structure comprising a first poly silicon layer and a first poly silicide layer formed in the first poly silicon layer, the eFuse structure comprising:
a second poly silicon layer; and
a second poly silicide layer formed in the second poly silicon layer, wherein an area of the second poly silicide layer is smaller than the first poly silicide layer.

2. The eFuse structure of claim 1, wherein the substrate further comprises an active region.

3. The eFuse structure of claim 2, wherein the electrical conduction structure formed in the active region is a MOS gate.

4. The eFuse structure of claim 3, wherein the electrical conduction structure comprises a gate insulating layer formed between the first poly silicon layer and the active region, and a first spacer is formed in the surround of the electrical conduction structure.

5. The eFuse structure of claim 1, wherein the substrate further comprises a STI (shallow trench isolation).

6. The eFuse structure of claim 5, wherein the substrate of the eFuse is formed on the STI (shallow trench isolation).

7. The eFuse structure of claim 6, further comprising a second spacer formed in the surround of the eFuse structure.

8. The eFuse structure of claim 1, wherein the eFuse structure and the electrical conduction structure have the same line width.

9. The eFuse structure of claim 8, wherein the first poly silicon layer and the second silicon layer have the same layer depth, and the layer depth of the second silicide layer is smaller than the layer depth of the first silicide.

10. An eFuse structure formed in a substrate, stacked gate structure formed in the substrate, and the thickness of the eFuse structure being thinner than the thickness of the gate structure.

11. The eFuse structure of claim 10, wherein the substrate further comprises an active region and the gate structure is formed in the active region.

12. The eFuse structure of claim 10, wherein the substrate further comprises a STI (shallow trench isolation) and the substrate of the eFuse is formed on the STI.

13. The eFuse structure of claim 10, wherein the gate structure further comprises a first poly silicon layer and a first silicide layer formed in the first poly silicon layer.

14. The eFuse structure of the claim 13, further comprising a second poly silicon layer and a second poly silicide layer formed in the second poly silicon layer.

15. The eFuse structure of claim 14, wherein the eFuse structure and the gate structure have the same line width.

16. The eFuse structure of claim 15, wherein the first poly silicon layer and the second silicon layer have the same layer depth, and the layer depth of the second silicide layer is smaller than the layer depth of the first silicide layer.

17. The eFuse structure of claim 10, further comprising a cathode and an anode for making electrical connections.
